(19) United States
(12) Patent Application Publication
(10) Pub. No.: US 2018/0292440 A1
(43) Pub. Date: Oct. 11, 2018

(54) ELECTROMAGNETIC SIGNAL DETECTING CIRCUIT AND CORRESPONDING DETECTING METHOD

(71) Applicant: CHING-KUANG C. TZUANG, Hsinchu County (TW)

(72) Inventor: CHING-KUANG C. TZUANG, Hsinchu County (TW)

(21) Appl. No.: 15/481,894

(22) Filed: Apr. 7, 2017

(51) Int. Cl. G01R 29/08

(52) U.S. Cl. CPC G01R 29/0871

(57) ABSTRACT

The invention discloses an electromagnetic signal detecting circuit and a corresponding method. Both the electromagnetic signal transported from a signal source and the reference signal transported from a reference source may be amplified and transported alternately at the same time to the processing circuit for further processing, or may be amplified respectively before the amplified signals being transported alternately to the processing circuit for further processing. In the modern technology, the switcher has almost a non-zero switching loss, and the gain of an amplifier is gradually degraded in the situation that the frequency of a signal to be amplified is gradually larger or smaller than a specific frequency range corresponding to the amplifier. Therefore, the invention may effectively detect the signal(s) no matter what the switching loss of the utilized switcher is and/or what the frequency of the electromagnetic signal(s) is.

### FIELD OF THE INVENTION

The present invention relates to the electromagnetic signal detecting circuit and detecting method, especially related to the electromagnetic signal detecting circuit and detecting method being suitable for the situations that the switcher loss of the switcher is not negligible or the gain of the amplifier is low due to the overly higher and/or lower frequency of the electromagnetic signal.

### BACKGROUND OF THE INVENTION

The Dicke switcher is the popular technology utilized to eliminate, at least reduce, the effects of the environment fluctuations or the noise appeared on the circuit during the step of receiving and measuring electromagnetic signals. As shown in FIG. 1A, the essential configuration of the Dicke switcher is briefly described as the below: the switcher 110 is switched between the electromagnetic signal source 101 and the reference signal 102, especially quickly and repeatedly between both sources 101/102. The amplifier 120 amplifies the signal transported from the source connected to the switcher 110 and then transports the amplified signal to the processing circuit 130 for further processing. The processing circuit 130 suppresses the noise by comparing the amplified electromagnetic signal and the amplified reference signal.

Nevertheless, all currently available switchers always have a non-zero switching loss and always have one or more disadvantages such as noise or low signal strength. Hence, the operational efficiency of the Dicke switcher always is degraded.

Moreover, for all currently available amplifiers, the gain of an amplifier is decreased in proportional to the difference between the electromagnetic signal frequency and a specific frequency range of the amplifier in the situation that the frequency of the electromagnetic signal is higher or lower than the specific frequency range. Further, the frequency range of the practical applications of the electromagnetic wave is continuously increased to the high frequency range and/or continuously decreased to the low frequency range during the past years. For example, the Terahertz-Gigahertz wave with the frequency range from 0.05 THz to 3 THz has been applied to the material structure exploration, the security detection and even the communication system during the recent years, and the electromagnetic waves with the frequency range lower than 100 KHz, even lower than 1 KHz, have been applied in the aeronautical radio, the submarine cable and the telephone telegram. Therefore, unless the specific frequency range of the amplifier utilized by the Dicke switcher is larger enough to cover the frequency range of all possibly appeared electromagnetic signal, even that of al possibly appeared reference signal, also unless the amplifier utilized by the Dicke switcher has enough gain outside its specific frequency range, the popularly applied conventional Dicke switcher always can not properly process the electromagnetic signal if the frequency of the electromagnetic signal is larger the specific frequency range of the Dicke switcher.

Accordingly, because the unavoidable switching loss of the currently available switchers, also because the amplifier gain unavoidably decreased if the frequency of the signal to be process exceeds its specific frequency range, the popularly utilized Dicke switcher can not effectively operate because the signal-to-noise ratio of the signal is not effectively increased. Note that the signals are continuously and alternately switched before they are amplified and then the processing circuit can not effectively suppress the noise.

Therefore, it is desired to develop new electromagnetic wave detecting circuit and detecting method so as to effectively suppress noise if the frequency of the electromagnetic wafer is higher or lower.

### SUMMARY OF THE INVENTION

The invention has two essential configurations. First configuration, amplify both the electromagnetic signal from the signal source and the reference signal from the reference source simultaneously (such as quickly and repeatedly turns on and turns off the different amplifiers for amplifying different signals) and alternately output the two kinds of amplified signals simultaneously so as to perform the following comparison and processing. Second configuration, amplify the electromagnetic signal from the signal source and the reference signal from the reference source respectively by using two different amplifiers, and then alternate outputs the two kinds of amplified signals by using the switcher (such as quickly and repeated turns on and turns off the different amplifiers for amplifying different signals) so as to perform the following comparison and processing.

The main difference between the invention and the popularly utilized Dicke switcher is the order of amplifying and switching. The invention amplifies and switches simultaneously or amplifies firstly and then switches later. That is to say, the invention may integrate the switcher and the amplifier so as to alternately switch the signal transported to the processing circuit by controllably turning on or turning different amplifiers respectively, also the invention may initially electrically connect the signal source and the reference source to the different amplifiers and then utilize the switcher electrically connected to these amplifiers to alternately switch which signal is transported to the processing circuit. In contrast, the popularly utilized Dicke switcher firstly switches and then amplifies. That is to say, in the popularly utilized Dicke switcher, the signal source and the reference source are initially electrically connected to the switcher respectively, and the amplifier electrically connects the switcher to the processing circuit. In this way, the signals are alternately transported through the switcher initially and then the alternately transported signals are amplified and transported to the processing circuit in sequence.

Significantly, the invention and the conventional popularly utilized Dicke switcher may utilize the equivalent device, the equivalent software, the equivalent firmware and others on the other portions. For example, the equivalent processing circuit, the equivalent signal source and the equivalent reference source. Besides, the invention does not limit the details of the utilized switcher and the utilized amplifier, any well-know, on-developed and to-be-appeared switcher and amplifier may be utilized by the invention.

### BRIEF DESCRIPTION OF THE DRAWINGS

FIG. 1 briefly illustrates the essential configuration of the Dicke switcher.

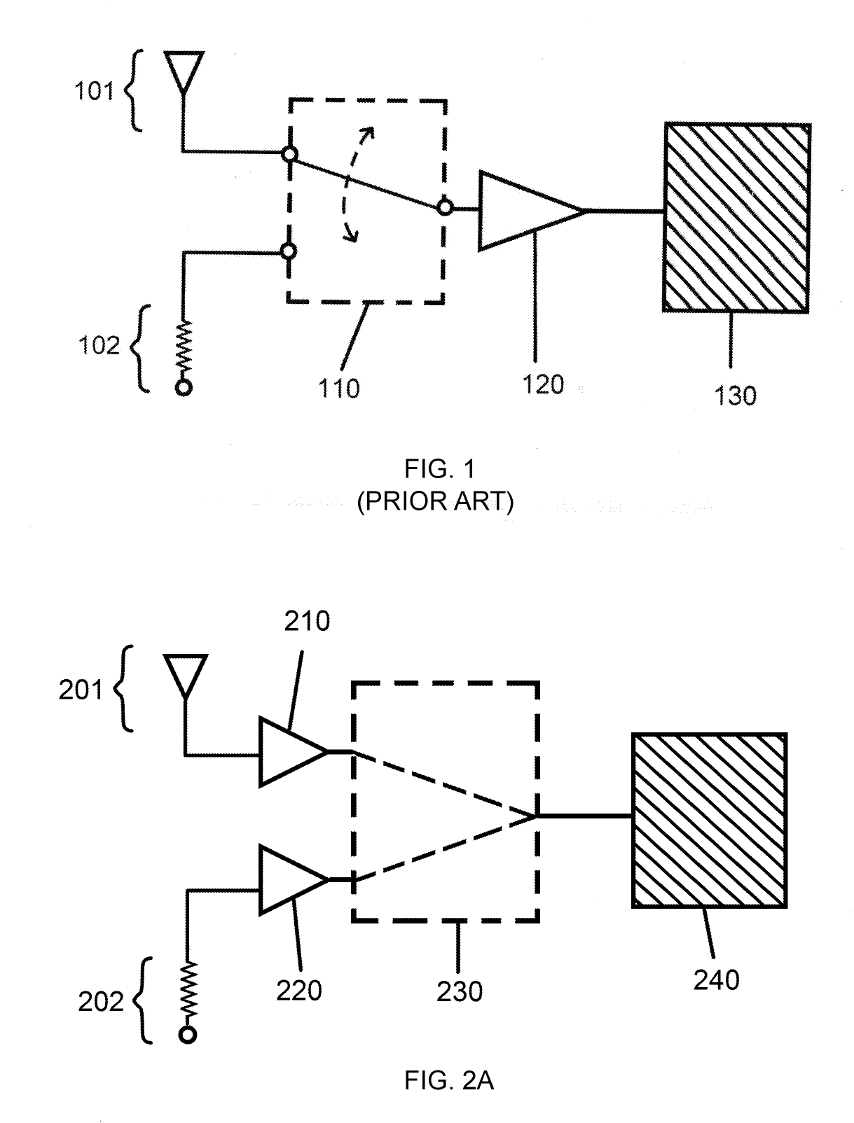

FIG. 2A to FIG. 2B briefly illustrates two essential configurations of the electromagnetic signal detecting circuit proposed by the invention respectively.

FIG. 3 briefly illustrates one exemplary embodiment of this invention.

FIG. 4A to FIG. 4C are the essential flowcharts of the electromagnetic wave detecting method of this invention.

### DETAILED DESCRIPTION OF THE INVENTION

Reference will now be made in details to specific embodiment of the present invention. Examples of these embodiments are illustrated in the accompanying drawings. While the invention will be described in conjunction with these specific embodiments, it will be understood that the intent is not to limit the invention to these embodiments. In fact, it is intended to cover alternates, modifications, and equivalents as may be included within the spirit and scope of the invention as defined by the appended claims. In the following description, numerous specific details are set forth in order to provide a thorough understanding of the present invention. The present invention may be practiced without at least one of these specific details. In other instances, the well-known portions are less or not described in detail in order not to obscure the present invention.

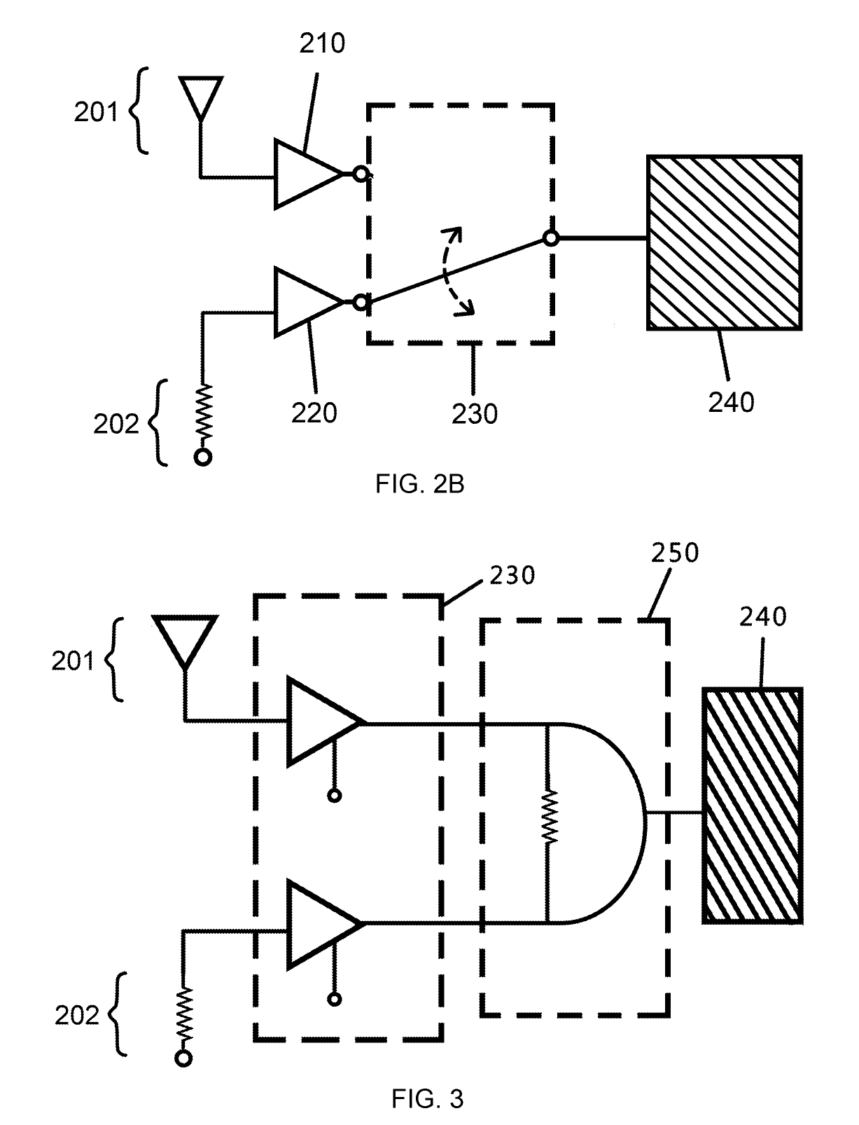

The first of the two essential configurations of the electromagnetic signal detecting circuit proposed by the invention is briefly illustrated in the FIG. 2A. The first amplifier 210 and the second amplifier 220 are electrically connected to the signal source 201 providing the electromagnetic signal and the reference source 202 providing the reference signal respectively. The switcher 230 fixedly electrically connects both the first amplifier 210 and the second amplifier 220 to the processing circuit 240, and also respectively controls the first amplifier 210 and the second amplifier 220 to be turned on or turned off. Of course, the first amplifier 210, the second amplifier 220 and the switcher 230 may be viewed collectively as a switcher with gain.

The main characteristic of such configuration is that different amplifiers electrically connect the signal source and the signal source to the processing circuit respectively and the switcher alternately turns on and turns off these two amplifiers so that the amplified electromagnetic signal and the amplified reference signal are alternately transported to the processing circuit. Significantly, these amplifiers are fixedly electrically connected to the processing circuit, and the switcher alternately transports the amplified electromagnetic signal and the amplified reference signal to the processing circuit by turning on or turning off these amplifiers individually. Hence, the effect of the switching loss may be minimized, or may be at least smaller than the effect of the switching loss of the conventional mechanical switcher or that of the conventional electrical switcher. Significantly, due to the decrement of the switching loss, no matter whether the gain of the amplifier is increased on not, the total gain of such configuration (the summarization of the amplifier gain and the switching loss) still may be increased.

The second of the two essential configurations of the electromagnetic signal detecting circuit proposed by the invention is briefly illustrated in the FIG. 2B. The first amplifier 210 and the second amplifier 220 are electrically connected to the signal source 210 providing the electromagnetic signal and the reference source 220 providing the reference signal respectively, and the switcher 230 is electrically connected to the first amplifier 210, the second amplifier 220 and the processing circuit 240.

The main characteristic of such configuration is that different amplifiers are utilized to amplify the electromagnetic signal to be processed and the reference signal to be utilized as reference before the amplified electromagnetic signal and the amplified reference signal being transported through the switcher to the processing circuit alternately. Significantly, the strength of each of the amplified electromagnetic signal and the amplified reference signal is larger than the strength of the electromagnetic signal and the reference signal (no matter higher signal voltage, more signal current or larger signal amplitude). Especially, the more the gain of these amplifiers is, the more the increments of the signal strength. Hence, although the switching loss of the switcher is unavoidable, both the amplified electromagnetic signal and the amplified reference signal may have better signal-to-noise ratio. Significantly, because the amplified electromagnetic signal and the amplified reference signal may reduce the effect of the switching loss, no matter whether the gain of the switcher is increased or not, the total gain of such configuration (the summarization of the amplifier gain and the switching loss) still may be increased.

In contrast, the popularly utilized Dicke switcher firstly utilizes the switcher to switch between the electromagnetic signal source and the reference signal source and then utilizes the amplifier to amplify the signal transported from the switcher. Because the signal-to-noise ratio of the signal transported through the switcher to the amplifier is degraded by the unavoidable switching loss, also because the gain of the amplifier directly amplify whole signal with lower signal-to-noise ratio, the processing circuit can not effectively suppress the noise.

Furthermore, in the situation that the frequency of the electromagnetic signal and/or the reference signal is higher or lower than specific frequency range that the popularly utilized amplifier may properly the signal(s), the electromagnetic signal detecting circuit proposed by the invention is more suitable than the popularly utilized Dicke switcher. Note that each currently available amplifier may have higher gain only on a specific frequency range and then the gain of any amplifier is decreased if the frequency of the signal to be amplified is higher or lower than the specific frequency range of the amplifier. In other words, the gain curve of any currently available amplifier is higher and stable if the signal frequency is in the specific frequency range of the amplifier but is gradually decreased if the signal frequency is gradually away the specific frequency range of the amplifier. Hence, if the frequency of the to-be-processed signal (no matter the electromagnetic signal or the reference signal) is too higher or too lower so that the amplifier can not properly amplify (or viewed as the absolute value of the gain of the amplifier is just a bit larger than one), because the popularly utilized Dicke switcher amplifies the signal has been degraded by the switching loss of the switcher, also because the invention amplifies the signal no later than the period that the signal is processed by the switcher, the invention may be less degraded by the switching loss during the process of transporting the signals from the signal source and the reference source to the processing circuit.

Particularly, because the main difference between the electromagnetic signal detecting circuit and the conventional Dicke switcher is the order of switching and amplifying the electromagnetic signal and the reference signal, the invention does not need to modify the amplifier and the switcher utilized by the conventional Dicky switch but only need to utilize the simple device(s) to turn on and turn off different amplifiers. Hence, to compare with the approach that designs and utilizes different amplifiers capable of properly amplifying the signals on the frequency range of both the electromagnetic signal and the reference signal, also to compare with the approach that designs and utilizes different switchers for reducing the switching loss, the electromagnetic signal detecting circuit proposed by the invention has at least the following advantages: low cost, easy to-be-practiced, easy to-be-designed and simple operation.

Significantly, the electromagnetic signal detecting circuit needs not to limit the details of each utilized amplifier (210/220), and any existed, on-developed and to-be-appeared amplifier may be utilized by the invention. For example, some embodiments of the invention utilize two equivalent amplifiers to form the first amplifier 210 and the second amplifier 220. In other words, the configuration of the first amplifier 210 may be fully equivalent to the configuration of the second amplifier 220, and the gains of both amplifiers are equivalent if the frequencies of the signals processed by the two amplifiers are equivalent. For example, some embodiments of the invention utilize two amplifiers with the identical gain curve to form the first amplifier 210 and the second amplifier 220. In other words, the only requirements is that the first amplifier 210 and the second amplifier 220 have identical gain at the identical frequency, but the device configuration of the first amplifier 210 and the second amplifier 220 may be different. For example, some embodiments of the invention utilizes the low noise amplifier (LNA) to form both the first amplifier 210 and the second amplifier 220 so as to further reducing the noise and increasing the signal-to-noise ratio, especially to further reducing the effect of the unavoidable switching loss during the period of transporting and/or switching the amplified electromagnetic signal and the amplified reference signal. Again, the utilized low noise amplifier may be any well-known, on-developed or to-be-appeared LNA.

Significantly, the electromagnetic signal detecting circuit needs not to limit the details of the utilized switcher 230, and any existed, on-developed and to-be-appeared switcher may be utilized by the invention. For example, some embodiments of the invention fixedly connect both the first amplifier 210 and the second amplifier 220 via the electric conductor to the processing circuit 240 and also utilizes the switcher 230 to respectively control whether the first amplifier 210 and the second amplifier 220 is turned and/or turned off respectively. In other words, the first amplifier 210 is turned on and the second amplifier 220 is turned off in the situation that the switcher 230 transports the amplified electromagnetic signal, and the first amplifier 210 is turned off and the second amplifier 220 is turned on in the situation that the switcher 230 transports the amplified reference signal. For example, some embodiments of the invention fixedly turn on both the first amplifier 210 and the second amplifier 220 and respectively controls the electric connection between the switcher 230 and each of the first amplifier 210 and the second amplifier 220. In other words, the switcher 230 is electrically connected to the first amplifier 210 and electrically separated away the second amplifier 220 in the situation that the switcher 230 transports the amplified electromagnetic signal, and the switcher 230 is electrically separated away the first amplifier 210 and electrically connected to the second amplifier 220 in the situation that the switcher 230 transports the amplified reference signal. It should be emphasized that the switching speed of the switcher 230 is decided by the required operation frequency of the processing circuit 240 for properly suppressing noise during the period of alternately receiving the amplified electromagnetic signal and the amplified reference signal. Further, to have higher switching speed when the amplified signal is alternately transported to the processing circuit 240, it is optional to controllably and respectively turn on or turn off both the first amplifier 210 and the second amplifier 220, and also is optional to utilize the electronic switcher for adjusting the electric connection between both the amplifiers 210/220 and the processing circuit 240. In general, the required switching speed of the switcher 230 is proportional to the frequency of the electromagnetic signal and/or the reference signal.

Furthermore, on different examples of the invention, the signal source 201 and/or the reference source 202 may be the source capable of providing the higher frequency signal or the lower frequency signal, because the proposed electromagnetic signal detecting circuit is more suitable than the conventionally Dicke switcher to effectively process the higher frequency signal or the lower frequency signal. For example, on some embodiments, the signal source 201 provides the electromagnetic signal with the frequency range from 50 GHZ to 650 GHz, i.e., these embodiments are suitable for the currently developed Terahertz-Gigahertz wave field. For example, on some embodiments, the signal source 201 provides the electromagnetic wave with the frequency ranges higher than 150 MHz or lower than 50 MHz, i.e., these embodiments are suitable to be operated with the frequency range that the gain of the currently available amplifier is lower. For example, because the proposed electromagnetic signal detecting circuit is less affected by the switching loss of the switcher than the popularly utilized Dicke switcher, on some embodiments of the invention, the signal source 201 may be the source providing the electromagnetic signal with less signal strength and also may be the source providing the electromagnetic signal providing the electromagnetic signal whose signal strength is briefly equivalent to or not less than the switching loss of the switcher 230. In other words, these embodiments are suitably applied to the situation that the signal strength is briefly equivalent to the switching loss of the switcher.

Nevertheless, the proposed electromagnetic signal detecting circuit does not need the details of the signal source 201 and the reference source 202, any well-known, on-developed and to-be appeared signal source 201 and reference source 202 may be utilized. For example, if the signal source receives the signal from the outside environment, in order to obtain the noise induced by the fluctuations of the outside environment (such as the spatial and temporal temperature and/or humidity fluctuations) and/or the internal noise of the device utilized to receive the signal, some embodiments of the invention are configured to position the signal source 201 close to but separated from the reference source 202, and some other embodiments of the invention are configured to position the signal source 201 and the reference source 202 in the equivalent environment with equivalent configuration. For example, if the signal source 201 is electrically connected to the antenna for receiving the electromagnetic wave, generating the electromagnetic signal accordingly and transporting the electromagnetic signal to the first amplifier 220, the reference source 202 may be positioned close to the antenna and may have the configuration similar with that of the antenna (such as similar material and/or similar shape) so as to measure the fluctuations of the temperature and the humidity on the surrounding environment of the antenna. For example, in order to measure the fluctuations of the amplified electromagnetic signal transported to the processing circuit 240 after the amplify and the switch steps, especially to measure whether the fluctuations of the amplified electromagnetic signal is induced by the fluctuations of the electromagnetic signal itself or induced by the noise appeared during the steps of amplify and switch, some embodiments of the invention positioned the reference source 202 close to the device utilized to amplify, to transport, to switch and to process the signal(s). For example, it is optional to position the reference source 202, the first amplifier 210, the second amplifier 220, the switcher 230 and the processing circuit 240 inside the same integrated circuits, especially in the same portion inside the integrated circuits. For example, it is also optional to position the reference source 202, the first amplifier 210, the second amplifier 220 and the switcher 230 inside the same integrated circuits, especially in the same portion inside the integrated circuits.

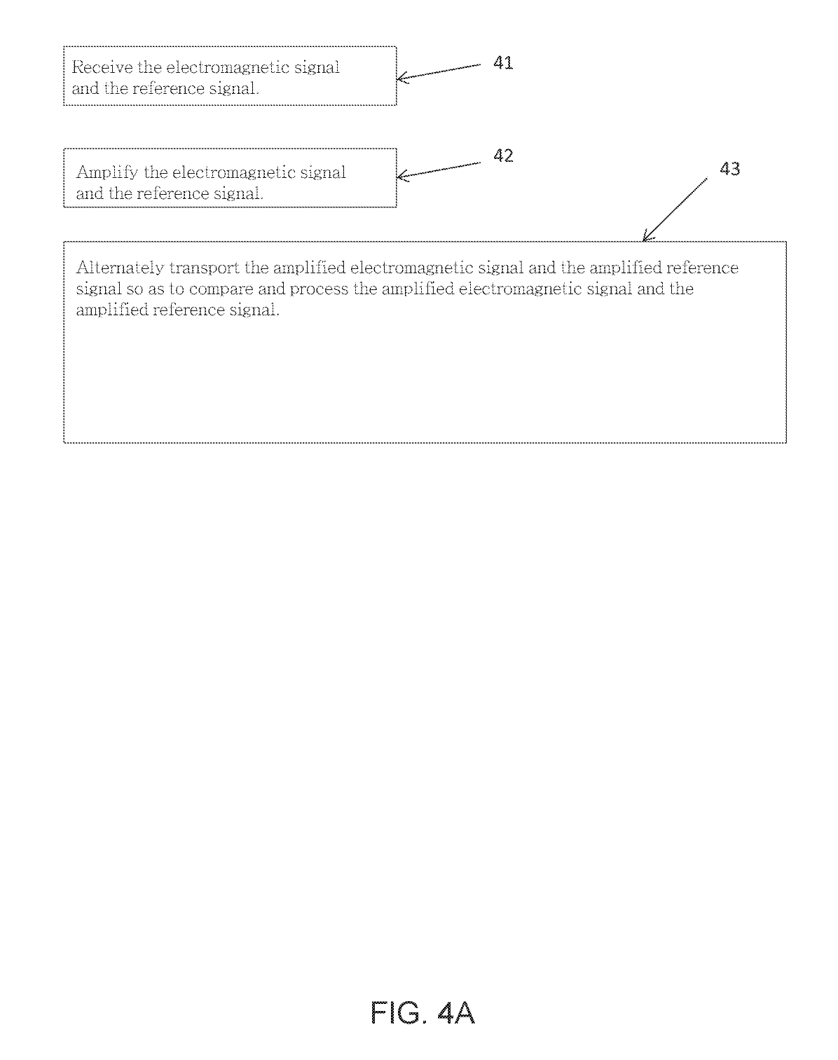

Besides, as shown in FIG. 3, in order to reduce the instability appeared in the situation that the outputs of both the first amplifier 210 and the second amplifier 220 are directly electrically connected to the same input terminal of the switcher 230, some embodiments of the invention utilizes the power combiner 250 to electrically connect the first amplifier 210 and the second amplifier 220 respectively, i.e., the amplified electromagnetic signal and the amplified reference signal are received by different input terminals of the power combiner 250. Also, the power combiner 250 may be electrically connected to the processing circuit 240 so that both the amplified electromagnetic signal and the amplified reference signal may be transported to the processing circuit 240. On these embodiments, both the first amplifier 210 and the second amplifier 220 are integrated into the switcher 230 but still may be turned on and turned off respectively so as to control how the amplified electromagnetic signal and the amplified reference signal are transported to the processing circuit 240 respectively. In other words, the switcher 230 may be viewed as a switcher with gain in the situation. Again, it should be emphasized that the invention does not limit the details of the power combiner 250, i.e., any well-known, on-developed and to-be-appeared power combiner may be utilized.

The embodiment shown in FIG. 3 has another advantage that the electromagnetic signal and the reference signal are transported directly to the power combiner 250 and the processing circuit 240, wherein the switch 230 is utilized to only control which of the first amplifier 210 and the second amplifier 220 is turned on or turned off but does not directly process the electromagnetic signal and the reference signal (or viewed as that both signals are not transported through the switcher 230). Hence, in the situation that the frequency of the electromagnetic signal and/or the reference signal is too higher or too lower and the gains of the first amplifier 210 and the second amplifier 220 is decreased correspondingly, the configuration shown in FIG. 3 may have a larger gain than the conventional Dicke switcher. That is to say, the amplified electromagnetic signal and the amplified reference signal transported to the processing circuit 240 may have better noise-to-signal ratio.

As a short summary, the proposed electromagnetic signal detecting circuit includes the signal source providing the electromagnetic signal and the reference source providing the reference signal, also includes the first amplifier electrically connected to the signal source for amplifying the electromagnetic signal, the second amplifier electrically connected to the reference source for amplifying the reference signal and the processing circuit configured to compare and process the amplified electromagnetic signal and the amplified reference signal. Particularly the proposed electromagnetic signal detecting circuit further including the switcher configured to alternately transport the amplified electromagnetic signal from the first amplifier to the processing circuit and the amplified reference signal from the second amplifier to the processing circuit. The essential configuration may be the “amplify and switch simultaneously” essential configuration as shown in FIG. 2A and also may be the “amplify firstly and then switch” essential configuration as shown in FIG. 2B.

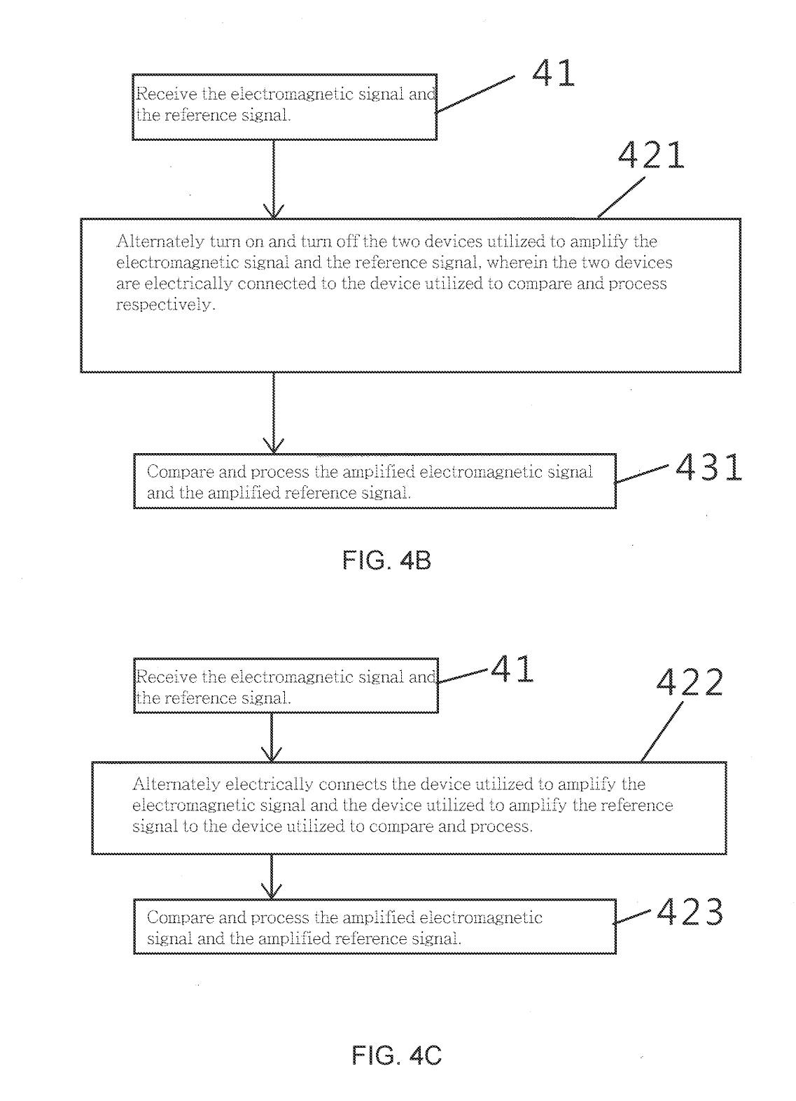

The electromagnetic signal detecting method processed by the invention is the operation method of the proposed electromagnetic signal detecting circuit, and the related details may be understood by referring the above paragraphs. Hence, FIG. 4A, FIG. 4B and FIG. 4C only simply describes the essential flowchart of the electromagnetic signal detecting method, but the other details are omitted. The essential flowchart of the proposed electromagnetic signal detecting method may be shown in FIG. 4A. Initially, as shown in step 41, receive the electromagnetic signal and the reference signal. Then, as shown in step 42, amplify the electromagnetic signal and the reference signal. Finally, as shown in step 43, alternately transport the amplified electromagnetic signal and the amplified reference signal so as to compare and process the amplified electromagnetic signal and the amplified reference signal. The proposed electromagnetic signal detecting method may use the two essential configurations of the proposed electromagnetic signal detecting circuit, as shown in FIG. 4B and FIG. 4C respectively. FIG. 4B is related to the “amplify and switch simultaneously” essential configuration. Initially, as shown in step 41, receive the electromagnetic signal and the reference signal. Then, as shown in step 421, alternately turn on and turn off the two devices utilized to amplify the electromagnetic signal and the reference signal, wherein the two devices are electrically connected to the device utilized to compare and process respectively. Finally, as shown in step 431, compare and process the amplified electromagnetic signal and the amplified reference signal. FIG. 4C is related to the “amplify firstly and then switch” essential configuration. Initially, as shown in step 41, receive the electromagnetic signal and the reference signal. Then, as shown in step 422, alternately electrically connects the device utilized to amplify the electromagnetic signal and the device utilized to amplify the reference signal to the device utilized to compare and process. Finally, as shown in step 432, compare and process the amplified electromagnetic signal and the amplified reference signal.

The presently disclosed embodiments should be considered in all respects to be illustrative and not restrictive. The scope of the invention is indicated by the appended claims rather than the foregoing description, and all variation which come within the meaning and range of equivalents thereof are intended to be embraced therein.

What is claimed is:

1. An electromagnetic signal detecting circuit, comprising:
a signal source configured to provide an electromagnetic signal;
a reference source configured to provide a reference signal;
a first amplifier electrically connected to the signal source and configured to amplify the electromagnetic signal;
a second amplifier electrically connected to the reference source and configured to amplify the reference signal;
a processing circuit configured to process the amplified electromagnetic signal and the reference signal; and
a switcher configured to alternately transport the amplified electromagnetic signal and the amplified reference signal to the processing circuit.

2. The electromagnetic signal detecting circuit as claimed in claim 1, wherein the switcher fixedly electrically connects both the first switcher and the second switcher to the processing circuit, and wherein the switcher controls the first amplifier and the second amplifier to be turned-on or to be turned-off respectively.

3. The electromagnetic signal detecting circuit as claimed in claim 1, wherein the switcher is electrically connected to the first amplifier or the second amplifier respectively, and wherein the switcher is electrically connected to the processing circuit.

4. The electromagnetic signal detecting circuit as claimed in claim 3, wherein both the first amplifier and the second amplifier is continuously turned-on.

5. The electromagnetic signal detecting circuit as claimed in claim 1, wherein the signal source is positioned away but close to the reference source.

6. The electromagnetic signal detecting circuit as claimed in claim 5, wherein the signal source and the reference source are positioned in the equivalent environment and have the equivalent configuration.

7. The electromagnetic signal detecting circuit as claimed in claim 1, wherein the signal source, the first amplifier, the second amplifier, the switcher and the processing circuit are packaged in the same integrated circuit.

8. The electromagnetic signal detecting circuit as claimed in claim 1, wherein the signal source, the first amplifier, the second amplifier and the switcher are packaged in the same portion of the same integrated circuit.

9. The electromagnetic signal detecting circuit as claimed in claim 1, wherein the first amplifier and the second amplifier are equivalent to each other.

10. The electromagnetic signal detecting circuit as claimed in claim 1, wherein the gain curve of the first amplifier is equivalent to the gain curve of the second amplifier.

11. The electromagnetic signal detecting circuit as claimed in claim 1, wherein both the first amplifier and the second amplifier are the low noise amplifier.

12. The electromagnetic signal detecting circuit as claimed in claim 1, wherein the signal source is electrically connected to an antenna, and wherein the signal source generates the electromagnetic signal according to the electromagnetic wave received by the antenna.

13. The electromagnetic signal detecting circuit as claimed in claim 1, further comprising at least one of the following:
the signal source providing the electromagnetic signal with the frequency range between 50 GHz to 650 GHz;
the signal source providing the electromagnetic signal with the frequency range higher than 150 MHz; and
the signal source providing the electromagnetic signal with the frequency range lower than 50 KHz.

14. The electromagnetic signal detecting circuit as claimed in claim 1, wherein the strength of the electromagnetic signal provided by the signal source is briefly equivalent to the switching loss of the switcher.

15. The electromagnetic signal detecting circuit as claimed in claim 1, wherein the strength of the electromagnetic signal provided by the signal source is briefly three times of the switching loss of the switcher.

16. An electromagnetic signal detecting method, comprising:
providing an electromagnetic signal and a reference signal;
amplifying the electromagnetic signal and the reference signal; and
alternately transporting the amplified electromagnetic signal and the amplified reference signal, so as to compare and process the amplified electromagnetic signal and the amplified reference signal.

17. The electromagnetic signal detecting method as claimed in claim 16, further comprising alternately turning on or turning off the two devices used to amplify the electromagnetic signal and amplify the reference signal, wherein both devices are electrically connected to the device used to compare and process respectively.

18. The electromagnetic signal detecting method as claimed in claim 16, further comprising alternately electrically connecting the device used to amplifying the electromagnetic signal or the device used to amplifying the reference signal to the device used to compare and process.

19. The electromagnetic signal detecting method as claimed in claim 16, further comprising at least one of the following:
positioning the source of the electromagnetic signal close to but away the source of the reference signal; and
positioning the source of the electromagnetic signal and the source of the reference signal in the equivalent environment with the equivalent configuration.

20. The electromagnetic signal detecting method as claimed in claim 16, further comprising at least one of the following:
positioning the source providing the reference signal, the device utilized to amplify the electromagnetic signal, the device utilized to amplify the reference signal, the device utilized to alternately transport and the device utilized to compare and process inside the same integrated circuit; and
positioning the source providing the reference signal, the device utilized to amplify the electromagnetic signal, the device utilized to amplify the reference signal and the device utilized to alternately transport inside the same integrated circuit.

21. The electromagnetic signal detecting method as claimed in claim 16, further comprising at least one of the following:
utilizing the equivalent amplifiers to amplify the electromagnetic signal and the reference signal;
utilizing the amplifiers with the equivalent gain curve to amplify the electromagnetic signal and the reference signal; and
utilizing the low noise amplifiers to amplify the electromagnetic signal and the reference signal.

22. The electromagnetic signal detecting method as claimed in claim 16, further comprising receiving the electromagnetic signal from an antenna, wherein the antenna receives an electromagnetic wave and then generates the electromagnetic signal accordingly.

23. The electromagnetic signal detecting method as claimed in claim 16, further comprising at least one of the following:
the signal source providing the electromagnetic signal with the frequency range between 50 GHz to 650 GHz;
the signal source providing the electromagnetic signal with the frequency range higher than 150 MHz; and
the signal source providing the electromagnetic signal with the frequency range lower than 50 KHz.

24. The electromagnetic signal detecting method as claimed in claim 16, further comprising at least one of the following:
the strength of the electromagnetic signal provided by the signal source is briefly equivalent to the switching loss of the switcher; and
the strength of the electromagnetic signal provided by the signal source is briefly three times of the switching loss of the switcher.
